(19) United States
(12) Patent Application Publication
(10) Pub. No.: US 2024/0332001 A1
(43) Pub. Date: Oct. 3, 2024

(54) ATOMIC LAYER DEPOSITION OF SILICON-CARBON-AND-NITROGEN-CONTAINING MATERIALS

(71) Applicant: Applied Materials, Inc., Santa Clara, CA (US)

(72) Inventors: Lakmal C. Kalutarage, San Jose, CA (US); Bhaskar Jyoti Bhuyan, San Jose, CA (US); Mark J. Saly, Santa Clara, CA (US); Jeffrey W. Anthis, Redwood City, CA (US)

(73) Assignee: Applied Materials, Inc., Santa Clara, CA (US)

(21) Appl. No.: 18/128,484

(22) Filed: Mar. 30, 2023

(51) Int. Cl. H01L 21/02

(52) U.S. Cl. CPC H01L 21/02167; H01L 21/0214; H01L 21/0217; H01L 21/02208; H01L 21/0228

(57) ABSTRACT

Exemplary methods of semiconductor processing may include providing a first precursor to a semiconductor processing chamber. A substrate may be disposed within a processing region of the semiconductor processing chamber. The substrate may define a feature. The methods may include contacting the substrate with the first precursor. The contacting may form a first portion of a silicon-carbon-and-nitrogen-containing material on the substrate. The methods may include providing a second precursor to the semiconductor processing chamber. The methods may include contacting the substrate with the second precursor. The contacting may form the silicon-carbon-and-nitrogen-containing material on the substrate. The silicon-carbon-and-nitrogen-containing material may be void free.

### TECHNICAL FIELD

The present technology relates to methods of semiconductor processing. More specifically, the present technology relates methods of forming materials on semiconductor structures.

### BACKGROUND

Integrated circuits are made possible by processes which produce intricately patterned material layers on substrate surfaces. Producing patterned material on a substrate requires controlled methods for forming and removing material. As device sizes continue to reduce, and device complexity continues to increase, producing structures has become increasingly complex. Developing structures may take many more operations to produce the complex patterning and material integration. Additionally, as the number of material layers being patterned during processing is expanding, producing materials that may have improved removal selectivity to other exposed materials is becoming a greater challenge, along with maintaining material properties.

Thus, there is a need for improved systems and methods that can be used to produce high quality devices and structures. These and other needs are addressed by the present technology.

### SUMMARY

Exemplary methods of semiconductor processing may include providing a first precursor to a semiconductor processing chamber. A substrate may be disposed within a processing region of the semiconductor processing chamber. The substrate may define a feature. The methods may include contacting the substrate with the first precursor. The contacting may form a first portion of a silicon-carbon-and-nitrogen-containing material on the substrate. The methods may include providing a second precursor to the semiconductor processing chamber. The methods may include contacting the substrate with the second precursor. The contacting may form the silicon-carbon-and-nitrogen-containing material on the substrate. The silicon-carbon-and-nitrogen-containing material is void free.

In some embodiments, the feature may be characterized by an aspect ratio of greater than or about 10:1. Either the first precursor or the second precursor may be or include a silicon-containing precursor. The silicon-containing precursor may include a halogen. Either the first precursor or the second precursor may be or include a carbon-and-nitrogen-containing precursor. The methods may include generating plasma effluents of the carbon-and-nitrogen-containing precursor. The methods may include providing an inert precursor to the semiconductor processing chamber, generating plasma effluents of the inert precursor, and contacting the silicon-carbon-and-nitrogen-containing material with plasma effluents of the inert precursor. The inert precursor may be or include argon, helium, or nitrogen. The methods may include, prior to providing the first precursor, providing an inhibitor to the semiconductor processing chamber and contacting the substrate with the inhibitor. The inhibitor may be or include a hydrocarbon. A temperature in the semiconductor processing chamber may be maintained less than or about 600° C.

Some embodiments of the present technology may encompass semiconductor processing methods. The methods may include providing a first precursor to a semiconductor processing chamber. A substrate may be disposed within a processing region of the semiconductor processing chamber. The substrate may define a feature characterized by an aspect ratio of greater than or about 10:1. The methods may include contacting the substrate with the first precursor. The contacting may form a first portion of a silicon-carbon-and-nitrogen-containing material on the substrate. The methods may include halting a flow of the first precursor. The methods may include purging the semiconductor processing chamber. The methods may include providing a second precursor to the semiconductor processing chamber. The methods may include contacting the substrate with the second precursor. The contacting may form the silicon-carbon-and-nitrogen-containing material on the substrate.

In some embodiments, the methods may include providing a third precursor to the semiconductor processing chamber. The third precursor may be or include an oxygen-containing precursor. The methods may include contacting the substrate with the third precursor. The contacting may form a silicon-carbon-oxygen-and-nitrogen-containing material on the substrate. One of the first precursor or the second precursor may be or include silicon-containing precursor. One of the first precursor or the second precursor may be or include a carbon-and-nitrogen-containing precursor or a carbon-and-oxygen-containing precursor. The methods may include generating plasma effluents of the carbon-and-nitrogen-containing precursor or the carbon-and-oxygen-containing precursor. Either the first precursor or the second precursor may be or include a carbon-nitrogen-and-oxygen-containing precursor. The silicon-carbon-and-nitrogen-containing material may be characterized by an oxygen content less than or about 50 at. %.

Some embodiments of the present technology may encompass semiconductor processing methods. The methods may include providing a first precursor to a semiconductor processing chamber. A substrate may be disposed within a processing region of the semiconductor processing chamber, wherein the substrate defines a feature. The methods may include contacting the substrate with the first precursor. The contacting may form a first portion of a silicon-carbon-and-nitrogen-containing material within the feature defined on the substrate. The methods may include purging the semiconductor processing chamber. The methods may include providing a second precursor to the semiconductor processing chamber. The second precursor may be or include a silicon-containing precursor or a carbon-and-nitrogen-containing precursor. The methods may include contacting the substrate with the second precursor, wherein the contacting forms the silicon-carbon-and-nitrogen-containing material within the featured defined on the substrate.

In some embodiments, the methods may include, prior to providing the first precursor, providing an inhibitor to the semiconductor processing chamber, generating plasma effluents of the inhibitor, contacting the substrate with the plasma effluents of the inhibitor. The contacting may remove active sites from a portion of substrate or deposits a carbon residue on a portion of the substrate.

Such technology may provide numerous benefits over conventional systems and techniques. For example, embodiments of the present technology may produce materials developed through atomic layer deposition. Additionally, through an atomic layer deposition, materials may be deposited that are seam and void free. Further, the materials may be densified to increase etch resistance. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

FIGS. 3A-3D show exemplary schematic cross-sectional structures in which material layers are included produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Silicon-carbon-and-nitrogen material may be used in semiconductor device manufacturing for a number of structures and processes. In gap filling operations, some processing may utilize plasma-enhanced deposition under process conditions in attempt to increase the directionality of the deposition, which may allow the deposited material to better fill features on the substrate. However, in some deposition processes, the deposited material may be characterized by relatively high amounts of hydrogen. The increased amounts of hydrogen may form a material that is less dense than other formed films.

As feature sizes continue to shrink, plasma-enhanced depositions may be challenged for narrow features, which may be further characterized by higher aspect ratios. For example, pinching of the feature may more readily occur due to deposition on sidewalls of the feature, which in small feature sizes may further restrict flow and deposition further into the feature, and may produce seams or voids in the deposited material. Conventional technologies have attempted to address the formation of seams or voids by performing intermittent etch operations to remove materials from the sidewalls of the features being filled. However, conventional etch operations have required many cycles to remove materials from the sidewalls of the features being filled to limit seam or void formation.

The present technology may overcome these limitations by performing an atomic layer deposition of material that may limit or prevent sidewall coverage during deposition, allowing improved fill operations to be performed. Additionally, a poisoning operation may be performed to limit material being deposited at an upper portion of the feature to be filled. The reduced deposition at the upper portion of the feature may prevent the feature from being pinched off. Additionally, the use of plasma during the deposition, either while providing one or more of the precursors or post-deposition, may densify the material and increase etch resistance.

Although the remaining disclosure will routinely identify specific deposition processes utilizing the disclosed technology, and will describe one type of semiconductor processing chamber, it will be readily understood that the processes described may be performed in any number of semiconductor processing chambers. Additionally, the present technology may be applicable to any number of semiconductor processes, beyond the exemplary process described below. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

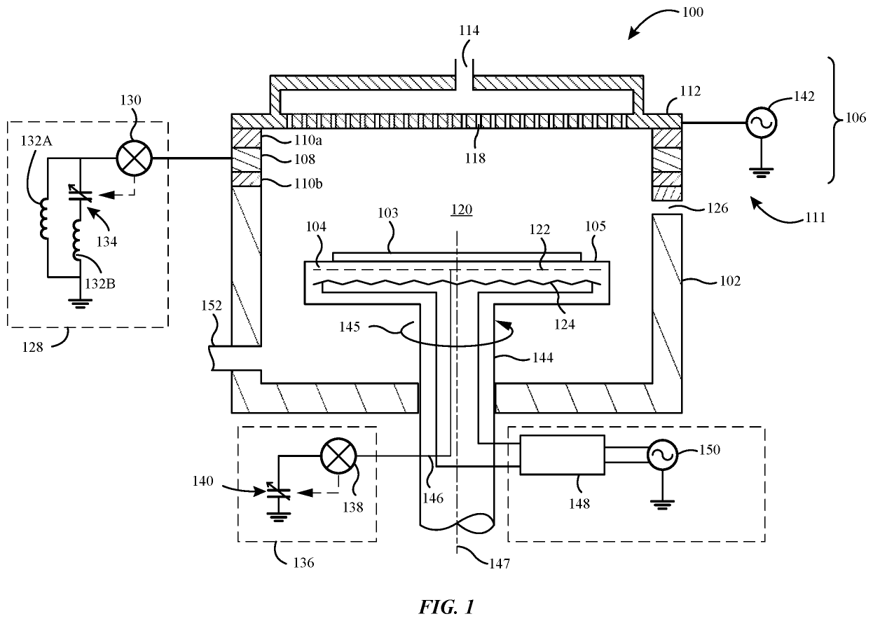

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as shown, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

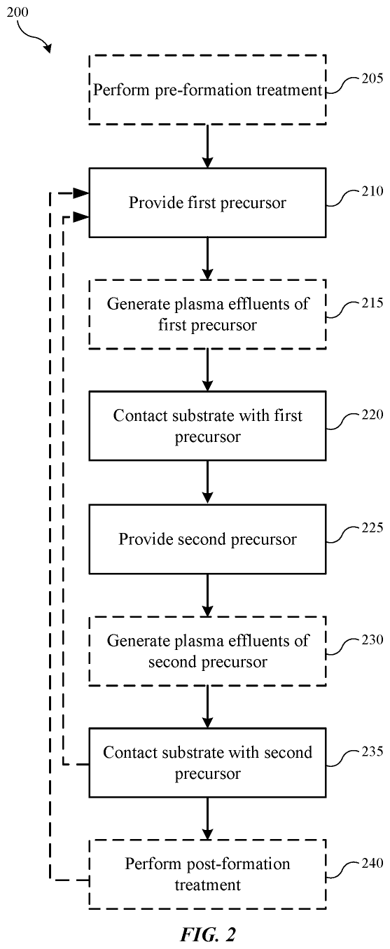

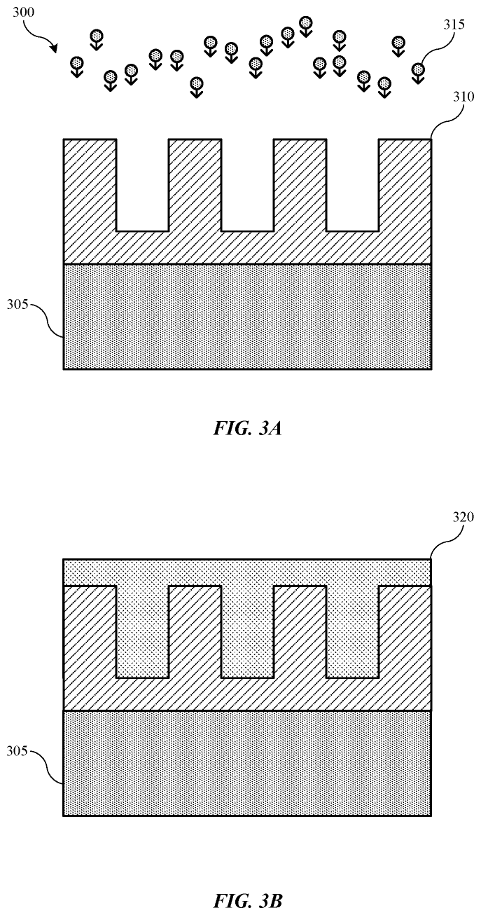

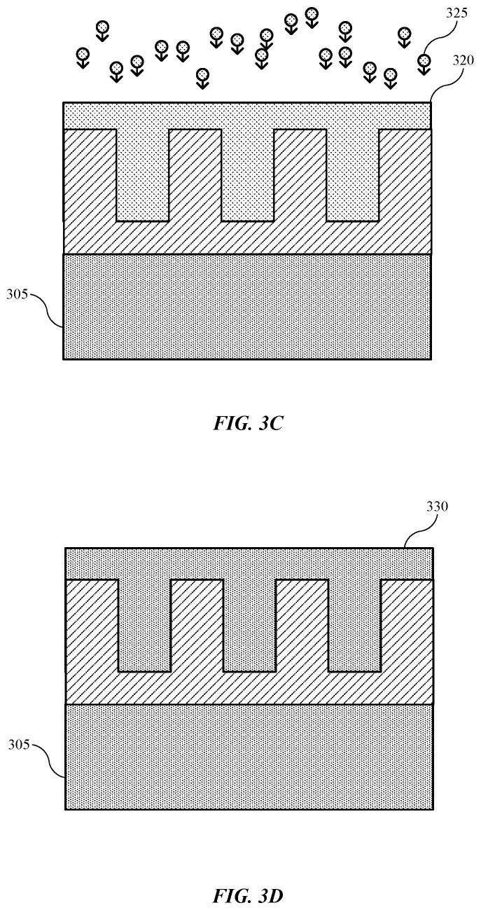

Processing chamber 100 may be utilized in some embodiments of the present technology for processing methods that may include formation, etching, or conversion of materials for semiconductor structures. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3D, the illustrations of which will be described in conjunction with the operations of method 200. It is to be understood that the figures illustrate only partial schematic views, and a structure 300 or a substrate 305 may contain any number of additional materials and features having a variety of characteristics and aspects as shown in the figures.

The substrate 305 may include any number of materials used in semiconductor processing. The substrate material may be or include silicon, germanium, dielectric materials including silicon oxide or silicon nitride, metal materials, or any number of combinations of these materials. The substrate 305 may include one or more substrate features formed in the substrate 305. The substrate 305 may include one or more materials 310 in which one or more features may be formed. The features may be characterized by any shape or configuration according to the present technology. In some embodiments, the features may be or include a trench structure or aperture formed within the substrate. In embodiments, the features may be may be characterized by any aspect ratios, or the height-to-width ratio of the structure, although in some embodiments the materials may be characterized by larger aspect ratios, which may not allow seam free or void free deposition utilizing conventional technology or methodology. For example, in some embodiments the aspect ratio of any layer of an exemplary structure may be greater than or about 10:1, greater than or about 11:1, greater than or about 12:1, greater than or about 13:1, greater than or about 14:1, greater than or about 15:1, greater than or about 16:1, or greater. Additionally, the features may be characterized by a reduced width, such as less than or about 100 nm, less than or about 80 nm, less than or about 60 nm, less than or about 50 nm, less than or about 40 nm, less than or about 30 nm, less than or about 20 nm, less than or about 18 nm, less than or about 16 nm, less than or about 14 nm, less than or about 12 nm, or less, including any fraction of any of the stated numbers. This combination of high aspect ratios and minimal widths may frustrate many conventional deposition operations.

Method 200 may include additional operations prior to initiation of the listed operations. For example, additional processing operations may include forming structures on a semiconductor substrate 305, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate 305 to a processing region of a semiconductor processing chamber, such as processing chamber 100 described above, or other chambers that may include components as described above. The substrate 305 may be deposited on a substrate support, which may be a pedestal such as substrate support 104, and which may reside in a processing region of the semiconductor processing chamber, such as a processing volume.

Embodiments of the present disclosure may form silicon-carbon-and-nitrogen-containing material through atomic layer deposition. The material may be formed by alternatively providing precursors such that the material intermittently forms. To deposit icon-carbon-and-nitrogen-containing material, the precursors may include silicon, carbon, and nitrogen. In embodiments, one of the precursors may include silicon and the other precursor may carbon and nitrogen with or without silicon. The precursor including silicon may be referred to as a silicon-containing precursor. The precursor including carbon and nitrogen may be referred to as a carbon-and-nitrogen-containing precursor. However, any combination of precursors including silicon, carbon, and nitrogen is contemplated. In some embodiments, a silicon-carbon-oxygen-and-nitrogen-containing material may be formed through atomic layer deposition. To incorporate oxygen, the precursors may further include oxygen. For example, an oxygen-containing precursor may be intermittently provided during the formation. Additionally or alternatively, either the silicon-containing precursor and/or the carbon-and-nitrogen-containing precursor may further include oxygen. For example, the silicon-containing precursor may be a silicon-and-oxygen-containing precursor, or the carbon-and-nitrogen-containing precursor may be a carbon-oxygen-and-nitrogen-containing precursor.

At optional operation 205, method 200 may include performing a pre-formation treatment. The pre-formation treatment may include providing an inhibitor to the semiconductor processing chamber. The inhibitor may include a hydrocarbon, such as an alkane, alkene, or an alkyne. The inhibitor may be provided with one or more inert precursors, such as argon, helium, or nitrogen. In some embodiments, an additional hydrogen-containing precursor, such as a diatomic hydrogen (H₂) may be provided with the inhibitor. After providing the inhibitor to the semiconductor processing chamber, plasma effluents of the inhibitor may be generated. The pre-formation treatment may include contacting the substrate with the plasma effluents of the inhibitor. The contacting may poison the substrate 305 or one or more materials 310. For example, the contacting may remove active sites from a portion of substrate or deposits a carbon residue on a portion of the substrate 305 or one or more materials 310. The contacting may deposit carbon on a portion of the substrate 305 or one or more materials 310. In embodiments, due to the non-conformality of the plasma effluents of the inhibitor, only an upper portion of the feature may be selectively poisoned. By poisoning the substrate 305 or one or more materials 310, the silicon-carbon-and-nitrogen-containing material may fill “V”-shaped features without seams or voids due the material forming in a bottom up manner. By filling in a bottom up manner, the feature may not be pinched off at the upper portion of the feature, which may result in the formation of seams or voids in the material.

In embodiments, the silicon-containing precursor may be any silicon-containing material useful in semiconductor processing, such as in atomic layer deposition processes. Exemplary silicon-containing precursors may be or include, but are not limited to, silane, disilane, or other organosilanes including cyclohexasilanes, silicon tetrafluoride, silicon tetrachloride, dichlorosilane, tetraethyl orthosilicate (TEOS), tetramethyldisiloxane (TMDSO), hexamethyldisiloxane (HMDSO), hexamethyldisilazane (HMDSN), and silicon tetrakis (ethylmethyamide) (TEMASi), alkylaminosilane, trisilylamine, alkylaminodisilane, alkylsilane, alkyloxysilane, alkylsilanol, and alkyloxysilanolas well as any other silicon-containing precursors that may be used in silicon-containing material formation. In some embodiments, the silicon-containing precursor may include a halogen, such as chlorine, bromine, iodine, or any other halogen. As discussed below, the carbon-and-nitrogen-containing precursor may include an amine, and a halogenated silane precursor may be necessary to react with the carbon-and-nitrogen-containing precursor including an amine. Additional silicon-containing precursors may be or include any of the following materials:

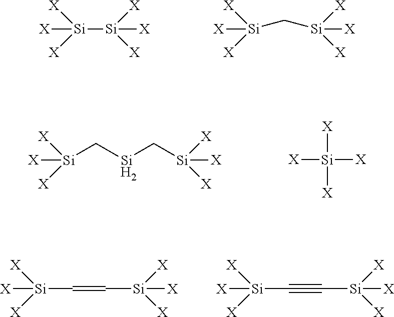

In the above materials, each X may be independently selected from chlorine, bromine, iodine, hydrogen, OR, NR₂, NCO, NCS, or CN, where R may be an alkyl.

The carbon-and-nitrogen-containing precursor may be any carbon-and-nitrogen-containing material useful in semiconductor processing, such as in atomic layer deposition processes. Exemplary carbon-and-nitrogen-containing precursors may be or include any of the following materials:

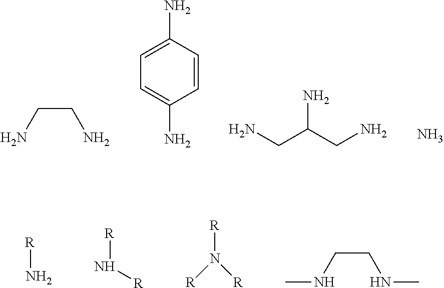

In the above materials, each R may be independently selected from methyl (CH₃), ethyl (CH₂CH₃), isopropyl (CH(CH₃)₂), tert-Butyl ((CH₃)₃C), or n-Butyl ((CH₂)₃CH₃).

Additionally, as previously discussed, the carbon-and-nitrogen-containing precursor may be a carbon-oxygen-and-nitrogen-containing precursor. Exemplary carbon-oxygen-and-nitrogen-containing precursors may be or include any of the following materials:

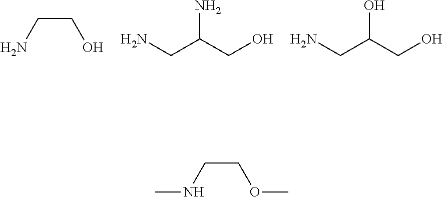

In some embodiments, a carbon-and-oxygen-containing precursor may be provided in conjunction with the carbon-and-nitrogen-containing precursor and/or the carbon-oxygen-and-nitrogen-containing precursor. Exemplary carbon-and-oxygen-containing precursors may be or include any of the following materials:

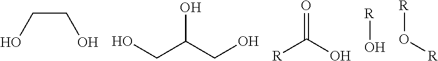

In the above materials, each R may be independently selected from methyl (CH₃), ethyl (CH₂CH₃), isopropyl (CH(CH₃)₂), tert-Butyl ((CH₃)₃C), n-Butyl ((CH₂)₃CH₃), or an alkene.

The oxygen-containing precursor may be any oxygen-containing material useful in semiconductor processing, such as in atomic layer deposition processes. For example, the oxygen-containing precursor may be molecular oxygen (O₂), water or steam (H₂O), hydrogen peroxide (H₂O₂), ozone (O₃), or ROH where R may be methyl (CH₃), ethyl (CH₂CH₃), isopropyl (CH(CH₃)₂), tert-Butyl ((CH₃)₃C), or n-Butyl ((CH₂)₃CH₃). In embodiments, in order to maintain oxygen content in the formed material, the oxygen-containing precursor may be diluted with another precursor such as an inert precursor. The oxygen-containing precursor may be less than or about 50 at. % based on the oxygen-containing precursor and the inert precursor.

As shown in FIG. 2, method 200 may include providing a first precursor to the semiconductor processing chamber, such as a processing region of the semiconductor processing chamber, at operation 210. Optionally, plasma effluents of the first precursor may be generated at optional operation 215. It is also contemplated that plasma effluents may be generated prior to providing the first precursor to the semiconductor processing chamber. Referring to FIG. 3A, the first precursor may have at least one reactive group that can form a bond with a group attached to a surface of the substrate 305 or one or more materials 310 in the processing region. Molecules of the first precursor 315 may react with the surface groups to form bonds linking the first precursor molecule to the surface of the substrate 305 or one or more materials 310. The reactions between molecules of the first precursor 315 and the groups on the surface of the substrate 305 or one or more materials 310 may continue until most or all the surface groups are bonded to a reactive group on molecules of the first precursor 315. As shown in FIG. 3B, a first portion of a silicon-carbon-and-nitrogen-containing material 320 may be formed at operation 220. The formation of the first portion of the silicon-carbon-and-nitrogen-containing material 320 may block further reaction between molecules of the first precursor 315 in the first precursor effluent and the substrate 305 or one or more materials 310.

The first precursor effluent may remain in the processing region for a period of time to nearly or completely form the first portion of the silicon-carbon-and-nitrogen-containing material 320. To form the silicon-carbon-and-nitrogen-containing material according to embodiments of the present technology, precursors may be delivered in alternating pulses to grow the material. In some embodiments, the pulse time of the first precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

Method 200 may also include an operation to purge or remove the first precursor effluents from the processing region following the formation of the first portion of the silicon-carbon-and-nitrogen-containing material 320. The method 200 may include halting a flow of the first precursor prior to purging effluents of the first precursor. The effluents of the first precursor may be removed by pumping them out of the processing region for a period of time ranging from about 10 seconds to about 100 seconds. Additional exemplary time ranges may include about 20 seconds to about 50 seconds, and 25 seconds to about 45 seconds, among other exemplary time ranges. However, in some embodiments, increased purge time may begin to remove reactive sites, which may reduce uniform formation. Accordingly, in some embodiments the purge may be performed for less than or about 60 seconds, and may be performed for less than or about 50 seconds, less than or about 40 seconds, less than or about 30 seconds, or less. In some embodiments, a purge gas may be introduced to the processing region to assist in the removal of the effluents. Exemplary purge gases include helium and nitrogen, among other purge gases.

After the removal of the first precursor effluents, a second precursor may be provided to the semiconductor processing chamber at operation 225 as shown in FIG. 3C. Optionally, plasma effluents of the second precursor may be generated at optional operation 230. It is also contemplated that plasma effluents may be generated prior to providing the second precursor to the semiconductor processing chamber. The second precursor may have at least one reactive group that can form bonds with unreacted reactive groups of the first precursor that formed the first portion of the silicon-carbon-and-nitrogen-containing material 320. Molecules of the second precursor 325 may react with the unreacted reactive groups of the first precursor to form bonds linking molecules of the second precursor 325 to molecules of the first precursor 315. The reactions between molecules of the second precursor 325 and molecules of the first precursor 315 may continue until most or all the unreacted reactive groups on molecules of the first precursor 315 have reacted with molecules of the second precursor 325. As shown in FIG. 3D, the contact between the second precursor and the first portion of the silicon-carbon-and-nitrogen-containing material 320 may form a silicon-carbon-and-nitrogen-containing material 330, such as SiCN, at operation 235. The formation of the silicon-carbon-and-nitrogen-containing material 330 may block further reaction between molecules of the second precursor 325 in the second precursor effluent and the first portion of the silicon-carbon-and-nitrogen-containing material 320.

Similar to the first precursor, the second precursor effluent may remain in the processing region for a period of time to nearly or completely form the silicon-carbon-and-nitrogen-containing material 330. As previously discussed, to form silicon-carbon-and-nitrogen-containing material according to embodiments of the present technology, precursors may be delivered in alternating pulses to grow the material. In some embodiments, the pulse time of the second precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

In some embodiments, the first precursor may be pulsed for longer periods of time than the second precursor. By increasing the residence time of the first precursor, improved adhesion may be produced across the substrate 305 or one or more materials 310. The second precursor may then more readily react with the ligands of the first precursor, and thus the second precursor may be pulsed for less time, which may improve throughput. For example, in some embodiments, the second precursor may be pulsed for less than or about 90% of the time the first precursor is pulsed. The second precursor may also be pulsed for less than or about 80% of the time the first precursor is pulsed, less than or about 70% of the time the first precursor is pulsed, less than or about 60% of the time the first precursor is pulsed, less than or about 50% of the time the first precursor is pulsed, less than or about 40% of the time the first precursor is pulsed, less than or about 30% of the time the first precursor is pulsed, or less.

Method 200 also includes an operation to purge or remove the second precursor effluents from the processing region following the formation of the silicon-carbon-and-nitrogen-containing material 330. The method 200 may include halting a flow of the second precursor prior to pursing the effluents of the second precursor. The effluents of the second precursor may be removed by pumping them out of the processing region for a period of time ranging from about 10 seconds to about 100 seconds. Additional exemplary time ranges may include about 20 seconds to about 50 seconds, and 25 seconds to about 45 seconds, among other exemplary time ranges. In some embodiments, a purge gas may be introduced to the processing region to assist in the removal of the effluents. Exemplary purge gases include helium and nitrogen, among other purge gases.

In embodiments, there may be a determination of whether a target thickness of the of as-deposited material on the substrate 305 or one or more materials 310 has been achieved following one or more cycles of forming the silicon-carbon-and-nitrogen-containing material 330. If a target thickness of as-deposited material has not been achieved, another cycle of providing the first precursor and second precursor may be performed. If a target thickness of as-deposited material has been achieved, another cycle of providing the first precursor and second precursor may not be started. Exemplary numbers of cycles for the formation of the silicon-carbon-and-nitrogen-containing material 330 may include 1 cycle, or may include greater than 2 cycles, 5 cycles, 10 cycles, 25 cycles, 50 cycles, 100 cycles, or more. Additional exemplary ranges for the number of cycles may include 50 cycles to 2000 cycles, 50 cycles to 1000 cycles, and 100 cycles to 750 cycles, among other exemplary ranges. Exemplary ranges of target thickness to discontinue further cycles of forming silicon-carbon-and-nitrogen-containing material 330 include less than or about 20 nm. Additional exemplary thickness ranges may include less than or about 18 nm, less than or about 16 nm, less than or about 15 nm, less than or about 14 nm, less than or about 13 nm, less than or about 12 nm, or less.

As previously discussed, the first precursor, the second precursor, or both may include oxygen, such that the silicon-carbon-and-nitrogen-containing material 330 may include oxygen. Alternatively, a separate oxygen-containing precursor may be provided during the formation of the silicon-carbon-and-nitrogen-containing material 330, such as to form a silicon-carbon-oxygen-and-nitrogen-containing material. The oxygen-containing precursor may be provided with the first precursor or the second precursor. Additionally or alternatively, the oxygen-containing precursor may be provided separately either after the first precursor or the second precursor. In embodiments, the first precursor, the second precursor, and the oxygen-containing precursor may be provided in any sequence with each cycle including a different order of precursors or number of precursors per cycle.

Similar to the first precursor and the second precursor, the oxygen-containing precursor may be provided to the semiconductor processing chamber. Optionally, plasma effluents of the oxygen-containing precursor may be generated. It is also contemplated that plasma effluents may be generated prior to providing the oxygen-containing precursor to the semiconductor processing chamber. The oxygen-containing precursor may have at least one reactive group that can form bonds with unreacted reactive groups on the substrate 305, the one or more materials 310, the first portion of the silicon-carbon-and-nitrogen-containing material 320, or the silicon-carbon-and-nitrogen-containing material 330, whichever is exposed and being contacted by the effluents of the oxygen-containing precursor. Molecules of the oxygen-containing precursor may react with exposed unreacted reactive groups to form bonds linking molecules of the oxygen-containing precursor to molecules of the exposed material. The reactions between molecules of the oxygen-containing precursor and molecules of the exposed material may continue until most or all the unreacted reactive groups on molecules of the oxygen-containing precursor have reacted with molecules of the exposed material. Alternatively, the reactions between molecules of the oxygen-containing precursor and molecules of the exposed material may continue until desired oxygen incorporation is achieved. The contact between the oxygen-containing precursor and the exposed material may ultimately lead to forming a silicon-carbon-oxygen-and-nitrogen-containing material, such as SiCON.

Similar to the first precursor and the second precursor, the oxygen-containing precursor effluent may remain in the processing region for a period of time to nearly or completely form the silicon-carbon-oxygen-and-nitrogen-containing material. As previously discussed, to form silicon-carbon-oxygen-and-nitrogen-containing material according to embodiments of the present technology, precursors may be delivered in alternating pulses to grow the material. In some embodiments, the pulse time of the oxygen-containing precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

Method 200 also includes an operation to purge or remove the oxygen-containing precursor effluents from the processing region following the formation of the silicon-carbon-oxygen-and-nitrogen-containing material. The method 200 may include halting a flow of the oxygen-containing precursor prior to pursing the effluents of the oxygen-containing precursor. The effluents of the oxygen-containing precursor may be removed by pumping them out of the processing region for a period of time ranging from about 10 seconds to about 100 seconds. Additional exemplary time ranges may include about 20 seconds to about 50 seconds, and 25 seconds to about 45 seconds, among other exemplary time ranges. In some embodiments, a purge gas may be introduced to the processing region to assist in the removal of the effluents. Exemplary purge gases include helium and nitrogen, among other purge gases.

As previously discussed, plasma effluents of the first precursor, the second precursor, and/or the oxygen-containing precursor may be generated. In embodiments, only plasma effluents of the carbon-and-nitrogen-containing precursor and/or the oxygen-containing precursor may be generated, while the silicon-containing precursor may be plasma-free. By generating plasma effluents of one or more precursors, directionality of the effluent may be increased, which may encourage deposition of material that is seam free and void free. When plasma is generated, one or more inert precursors, such as argon, helium, or nitrogen, may be provided with the precursor to assist in generating plasma effluents as well as distribute the precursor. The plasma of the inert precursor may be a capacitively coupled plasma (CCP) plasma, a plasma formed in a remote plasma source (RPS), or a microwave plasma.

After forming the silicon-carbon-and-nitrogen-containing material 330, method 200 may include performing a post-formation treatment at optional operation 240. The post-formation treatment may include providing an inert precursor to the semiconductor processing chamber, generating plasma effluents of the inert precursor, and contacting the silicon-carbon-and-nitrogen-containing material 330 with plasma effluents of the inert precursor. The inert precursor may be or include any inert precursors, such as argon, helium, or nitrogen. Similar to the optional plasma of the first precursor, the second precursor, and/or the oxygen-containing precursor, the plasma of the inert precursor may be a capacitively coupled plasma (CCP) plasma, a plasma formed in a remote plasma source (RPS), or a microwave plasma. The plasma effluents of the inert precursor may regenerate reactive species on surfaces of exposed materials, which may allow for continued growth to occur. The plasma effluents of the inert precursor may densify the material by outgassing hydrogen.

The formation rate of the silicon-carbon-and-nitrogen-containing material 330 may depend on the temperature of the substrate 305 as well as the temperature of the precursors that flow into the processing region. Exemplary substrate temperatures during the formation operations may be greater than or about 50° C., greater than or about 75° C., greater than or about 100° C., greater than or about 125° C., greater than or about 150° C., greater than or about 175° C., greater than or about 200° C., greater than or about 250° C., greater than or about 300° C., greater than or about 350° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., or higher. By maintaining the substrate temperature elevated, such as above or about 400° C. in some embodiments, an increased number of nucleation sites may be available along the substrate 305, which may improve formation and reduce void formation by improving coverage at each location.

The formation rate of the silicon-carbon-and-nitrogen-containing material 330 may also depend on the pressure in the processing region. Exemplary pressures in the processing region may range from about 1 mTorr to about 100 Torr. In embodiments, the pressure may be less than or about 100 Torr, such as less than or about 90 Torr, less than or about 80 Torr, less than or about 70 Torr, less than or about 60 Torr, less than or about 50 Torr, less than or about 40 Torr, less than or about 30 Torr, less than or about 20 Torr, less than or about 10 Torr, less than or about 5 Torr, less than or about 1 Torr, or less.

The embodiments of the present disclosure may allow for the deposition of silicon-carbon-and-nitrogen-containing materials characterized by a dielectric constant of less than or about 7, such as less than or about 6.5, less than or about 6, less than or about 5.5, less than or about 5, less than or about 4.5, less than or about 4, less than or about 3.9, less than or about 3.8, less than or about 3.7, less than or about 3.6, less than or about 3.5, or less. While composition of the material may be tuned based on flow rate of precursors, pulse times, plasma characteristics, etc., the present technology may allow for the deposition of silicon-carbon-and-nitrogen-containing materials characterized by a nitrogen content of less than or about 50 at. %, such as less than or about 48 at. %, less than or about 46 at. %, less than or about 44 at. %, less than or about 42 at. %, less than or about 40 at. %, less than or about 38 at. %, less than or about 36 at. %, less than or about 34 at. %, less than or about 32 at. %, less than or about 30 at. %, or less. Similarly, the present technology may allow for the deposition of silicon-carbon-and-nitrogen-containing materials characterized by a carbon content of less than or about 30 at. %, such as less than or about 28 at. %, less than or about 26 at. %, less than or about 24 at. %, less than or about 22 at. %, less than or about 20 at. %, less than or about 18 at. %, less than or about 16 at. %, less than or about 14 at. %, less than or about 12 at. %, less than or about 10 at. %, or less. Further, the present technology may allow for the deposition of silicon-carbon-and-nitrogen-containing materials characterized by an oxygen content of less than or about 10 at. %, such as less than or about 9 at. %, less than or about 8 at. %, less than or about 7 at. %, less than or about 6 at. %, less than or about 5 at. %, less than or about 4 at. %, less than or about 3 at. %, less than or about 2 at. %, or less.

The increased density of the materials of the present technology may result in an increased wet etch rate ratio (WERR). WERR may be defined as the relative etch rate of the silicon-carbon-and-nitrogen-containing material, such as in Å/min, in a particular etchant, such as dilute HF, compared to the etch rate of a thermally-grown silicon oxide material formed on the same substrate. A WERR of 1.0 means the material in question has the same etch rate as a thermal oxide material, while a WERR of less than 1 means the silicon-carbon-and-nitrogen-containing material etches at a slower rate than thermal oxide. In embodiments, the WERR of the silicon-carbon-and-nitrogen-containing material may be characterized by a WERR of less than or about 1, such as less than or about 0.9, less than or about 0.8, less than or about 0.7, less than or about 0.6, less than or about 0.5, less than or about 0.4, less than or about 0.3, less than or about 0.2, less than or about 0.1, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a first precursor to a semiconductor processing chamber, wherein a substrate is disposed within a processing region of the semiconductor processing chamber, wherein the substrate defines a feature;
contacting the substrate with the first precursor, wherein the contacting forms a first portion of a silicon-carbon-and-nitrogen-containing material on the substrate;
providing a second precursor to the semiconductor processing chamber; and
contacting the substrate with the second precursor, wherein the contacting forms 8 the silicon-carbon-and-nitrogen-containing material on the substrate, and wherein the silicon-carbon-and-nitrogen-containing material is void free.

2. The semiconductor processing method of claim 1, wherein the feature is characterized by an aspect ratio of greater than or about 10:1.

3. The semiconductor processing method of claim 1, wherein either the first precursor or the second precursor comprises a silicon-containing precursor.

4. The semiconductor processing method of claim 3, wherein the silicon-containing precursor further comprises a halogen.

5. The semiconductor processing method of claim 1, wherein either the first precursor or the second precursor comprises a carbon-and-nitrogen-containing precursor.

6. The semiconductor processing method of claim 5, further comprising:
generating plasma effluents of the carbon-and-nitrogen-containing precursor.

7. The semiconductor processing method of claim 1, further comprising:
providing an inert precursor to the semiconductor processing chamber;
generating plasma effluents of the inert precursor; and
contacting the silicon-carbon-and-nitrogen-containing material with plasma effluents of the inert precursor.

8. The semiconductor processing method of claim 7, wherein the inert precursor comprises argon, helium, or nitrogen.

9. The semiconductor processing method of claim 1, further comprising:
prior to providing the first precursor, providing an inhibitor to the semiconductor processing chamber; and
contacting the substrate with the inhibitor.

10. The semiconductor processing method of claim 9, wherein the inhibitor comprises a hydrocarbon.

11. The semiconductor processing method of claim 1, wherein a temperature in the semiconductor processing chamber is maintained less than or about 600° C.

12. A semiconductor processing method comprising:
providing a first precursor to a semiconductor processing chamber, wherein a substrate is disposed within a processing region of the semiconductor processing chamber, wherein the substrate defines a feature characterized by an aspect ratio of greater than or about 10:1;
contacting the substrate with the first precursor, wherein the contacting forms a first portion of a silicon-carbon-and-nitrogen-containing material on the substrate;
halting a flow of the first precursor;
purging the semiconductor processing chamber;
providing a second precursor to the semiconductor processing chamber; and
contacting the substrate with the second precursor, wherein the contacting forms the silicon-carbon-and-nitrogen-containing material on the substrate.

13. The semiconductor processing method of claim 12, further comprising:
providing a third precursor to the semiconductor processing chamber, wherein the third precursor comprises an oxygen-containing precursor; and
contacting the substrate with the third precursor, wherein the contacting forms a silicon-carbon-oxygen-and-nitrogen-containing material on the substrate.

14. The semiconductor processing method of claim 12, wherein:
one of the first precursor or the second precursor comprises silicon-containing precursor; and
one of the first precursor or the second precursor comprises a carbon-and-nitrogen-containing precursor or a carbon-and-oxygen-containing precursor.

15. The semiconductor processing method of claim 14, further comprising:
generating plasma effluents of the carbon-and-nitrogen-containing precursor or the carbon-and-oxygen-containing precursor.

16. The semiconductor processing method of claim 12, wherein either the first precursor or the second precursor comprises a carbon-nitrogen-and-oxygen-containing precursor.

17. The semiconductor processing method of claim 16, wherein the silicon-carbon-and-nitrogen-containing material is characterized by an oxygen content less than or about 50 at. %.

18. The semiconductor processing method of claim 12, further comprising:
providing an inert precursor to the semiconductor processing chamber;
generating plasma effluents of the inert precursor; and
contacting the silicon-carbon-and-nitrogen-containing material with plasma effluents of the inert precursor, wherein the contacting densifies the silicon-carbon-and-nitrogen-containing material.

19. A semiconductor processing method comprising:
providing a first precursor to a semiconductor processing chamber, wherein a substrate is disposed within a processing region of the semiconductor processing chamber, wherein the substrate defines a feature;
contacting the substrate with the first precursor, wherein the contacting forms a first portion of a silicon-carbon-and-nitrogen-containing material within the feature defined on the substrate;
purging the semiconductor processing chamber;
providing a second precursor to the semiconductor processing chamber, wherein the second precursor comprises a silicon-containing precursor or a carbon-and-nitrogen-containing precursor; and
contacting the substrate with the second precursor, wherein the contacting forms the silicon-carbon-and-nitrogen-containing material within the featured defined on the substrate.

20. The semiconductor processing method of claim 19, further comprising:
prior to providing the first precursor, providing an inhibitor to the semiconductor processing chamber;
generating plasma effluents of the inhibitor; and
contacting the substrate with the plasma effluents of the inhibitor, wherein the contacting removes active sites from a portion of substrate or deposits a carbon residue on a portion of the substrate.
